(19) United States
(12) Patent Application Publication
(10) Pub. No.: US 2026/0255746 A1
(43) Pub. Date: Aug. 27, 2026

(54) Display Device

(71) Applicant: LG Display Co., Ltd., Seoul (KR)

(72) Inventors: JinWoo Hong, Seoul (KR); Hyunjik Bae, Daegu (KR); Doeon Park, Daegu (KR); Yong-ku Lee, Gimpo-si (KR); Jaebin Song, Seoul (KR)

(21) Appl. No.: 19/416,461

(22) Filed: Dec. 11, 2025

(30) Foreign Application Priority Data
Feb. 26, 2025 (KR) 10-2025-0025056

(51) Int. Cl. H10H 20/855; H10H 20/821; H10H 29/37; H10K 59/122; H10K 59/80

(52) U.S. Cl. CPC H10H 20/855; H10H 20/821; H10H 29/37; H10K 59/122; H10K 59/879

(57) ABSTRACT

A display device including a substrate, a planarization layer disposed on the substrate, a base portion and a protrusion portion disposed on the base portion, a light emitting element disposed on the planarization layer, a first electrode disposed on a part of the base portion adjacent to the protrusion portion, a light emitting layer disposed on the first electrode and a second electrode disposed on the light emitting layer, and an optical member having a bar shape disposed on the light emitting element, is disclosed. The display device allows to minimize the luminance deviation according to the viewing angle. The light emitting layer includes a first portion disposed in a center portion to overlap with an upper surface of the protrusion portion and a second portion surrounding the first portion and disposed at an end to overlap with a side surface of the protrusion portion.

### CROSS-REFERENCE TO RELATED APPLICATIONS

This application claims the priority under 35 U.S.C. §119(a) to the Republic of Korea Patent Application No. 10-2025-0025056 filed on February 26, 2025, the entire contents of which are hereby expressly incorporated by reference into the present application.

### TECHNICAL FIELD

The present disclosure relates to a display device, and more particularly, to a display device in which a luminance deviation according to a viewing angle is minimized.

### BACKGROUND

With the development of technologies in modern society, display devices are being used in various ways to provide information to users. Display devices are included in electronic signs that simply transmit visual information in one direction, as well as various electronic devices that require higher technology to check a user's input and provide information in response to the checked input.

For example, the display device may be included in a vehicle to provide various information to a driver and a passenger of the vehicle. However, the display device of the vehicle needs to display content appropriately so as not to interfere with the operation of the vehicle. For example, the display device needs to limit the display of content that may reduce concentration on driving while the vehicle is in operation.

### SUMMARY

An object to be achieved by the present disclosure is to provide a display device capable of controlling a viewing angle.

An object to be achieved by the present disclosure is to provide a display device in which a luminance deviation according to a viewing angle is improved.

An object to be achieved by the present disclosure is to provide a display device in which a luminance deviation according to a viewing angle, which may occur between degraded areas and non-degraded areas among emission areas, is minimized.

An object to be achieved by the present disclosure is to provide a display device in which display quality is improved by implementing uniform luminance.

An object to be achieved by the present disclosure is to provide a display device in which an effect of pixel shrinkage due to out-gassing is minimized.

Objects of the present disclosure are not limited to the above-mentioned objects, and other objects, which are not mentioned above, can be clearly understood by those skilled in the art from the following descriptions.

According to an aspect of the present disclosure, a display device includes a substrate, a planarization layer disposed on the substrate and including a base portion and a protrusion portion disposed on the base portion, a light emitting element disposed on the planarization layer and including a first electrode disposed on a part of the base portion adjacent to the protrusion portion, a light emitting layer disposed on the first electrode and a second electrode disposed on the light emitting layer, and an optical member having a bar shape disposed on the light emitting element. The light emitting layer includes a first portion disposed in a center portion and a second portion surrounding the first portion and disposed at an end. The first portion is disposed to overlap with an upper surface of the protrusion portion. The second portion is disposed to overlap with a side surface of the protrusion portion.

According to another aspect of the present disclosure, a display device includes a substrate including a display area in which a plurality of sub pixels is defined and a non-display area surrounding the display area, a planarization layer disposed on the substrate, a first light emitting element and a second light emitting element disposed in each of the plurality of sub pixels, a first optical member disposed on the first light emitting element and having a semi-cylindrical shape, and a second optical member disposed on the second light emitting element and having a semi-spherical shape, wherein the first light emitting element and the second light emitting element each include a first electrode, a light emitting layer, and a second electrode. The light emitting layer includes a first portion disposed in a center portion, and a second portion disposed at an edge of the first portion. The planarization layer includes a protrusion portion disposed to overlap with the first light emitting element. Accordingly, it is possible to minimize the luminance deviation according to the viewing angle.

Other detailed matters of the embodiments are included in the detailed description and the drawings.

According to the present disclosure, it is possible to reduce the luminance deviation according to the viewing angle that may occur between the degraded light emission areas and the non-degraded light emission area.

According to the present disclosure, it is possible to improve display quality by implementing uniform luminance.

According to the present disclosure, it is possible to minimize the effect of pixel shrinkage due to out-gassing.

The effects according to the embodiments of the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplary view of a display device according to an exemplary embodiment of the present disclosure.

FIG. 2 is a functional block diagram of a display device according to an exemplary embodiment of the present disclosure.

FIG. 3 is an enlarged plan view of a pixel of a display device according to an exemplary embodiment of the present disclosure.

FIG. 4 is a cross-sectional view taken along IV-IV’ of FIG. 3.

FIG. 5 is a cross-sectional view taken along V-V' in FIG. 3.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

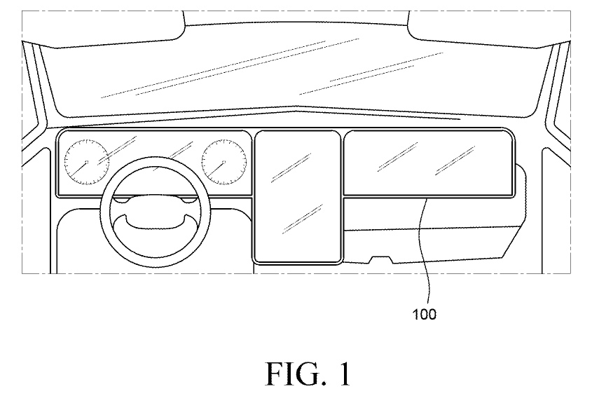

FIG. 1 is an exemplary view of a display device according to an exemplary embodiment of the present disclosure.

Referring to FIG. 1, a display device 100 may be disposed on at least a part of a dashboard of a vehicle. The dashboard of the vehicle may include a configuration disposed in front of front seats (e.g., driver's seat and passenger seat) of the vehicle. For example, an input configuration for manipulating various functions (e.g., an air conditioner, an audio system, and a navigation system) inside the vehicle may be disposed on the dashboard of the vehicle.

The display device 100 may be disposed on the dashboard of the vehicle and operate as an input unit for manipulating at least some of various functions of the vehicle. The display device 100 may provide various information related to the vehicle, for example, driving information of the vehicle (for example, a current speed of the vehicle, a remaining fuel amount, and a driving distance), information on parts of the vehicle (for example, a damage degree of a vehicle tire), and the like.

The display device 100 may be disposed across the driver seat and the front passenger seat disposed in the front seats of the vehicle. The user of the display device 100 may include a driver of the vehicle and a passenger riding in the passenger seat. Both the driver and the passenger of the vehicle may use the display device 100.

Only a part of the display device 100 illustrated in FIG. 1 may be illustrated. The display device 100 illustrated in FIG. 1 may represent a display panel among various configurations included in the display device 100. Specifically, for example, the display device 100 illustrated in FIG. 1 may represent at least a part of a display area and a non-display area of a display panel. Among the configurations of the display device 100, configurations other than those illustrated in FIG. 1 may be mounted inside (or at least a portion) of the vehicle.

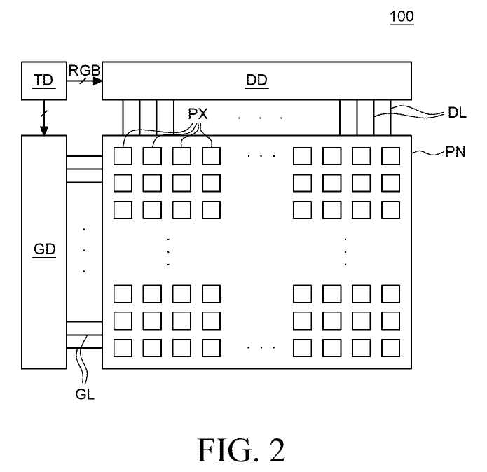

FIG. 2 is a functional block diagram of a display device according to an exemplary embodiment of the present disclosure.

An electroluminescent display device may be applied to a display device according to an exemplary embodiment of the present disclosure. The electroluminescent display device may be an organic light emitting diode display device, a quantum-dot light emitting diode display device, or an inorganic light emitting diode display device.

Referring to FIG. 2, the display device 100 may include a display panel PN, a data driving circuit DD, a gate driving circuit GD, and a timing controller TD.

The display panel PN may generate an image to be provided to the user. For example, the display panel PN may generate and display an image to be provided to the user through a plurality of pixels PX in which pixel circuits are disposed.

The data driving circuit DD, the gate driving circuit GD, and the timing controller TD may provide signals for the operation of each pixel PX through signal lines. For example, the signal lines for providing the signals for the operation of each pixel PX may include a plurality of data lines DL and a plurality of gate lines GL.

The plurality of data lines DL may include a plurality of lines arranged in a column direction and connected to pixels PX arranged in one column direction, and the plurality of gate lines GL may include a plurality of lines arranged in a row direction and connected to pixels PX arranged in one row direction.

In some cases, the display device 100 may further include a power unit. In this case, a signal for operating the pixel PX may be provided through a power line connecting the power unit and the display panel PN. Depending on the exemplary embodiment, the power unit may provide power to the data driving circuit DD and the gate driving circuit GD. The data driving circuit DD and the gate driving circuit GD may be driven based on power provided from the power unit.

For example, the data driving circuit DD may apply a data signal to each pixel PX through a plurality of data lines DL, the gate driving circuit GD may apply a gate signal to each pixel PX through a plurality of gate lines GL, and the power unit may supply a power voltage to each pixel PX through a power voltage supply line.

The timing controller TD may control the data driving circuit DD and the gate driving circuit GD. For example, the timing controller TD may rearrange digital video data input from the outside to match the resolution of the display panel PN and supply the rearranged digital video data to the data driving circuit DD.

The data driving circuit DD may convert digital video data input from the timing controller TD into an analog data voltage based on a data control signal and supply the analog data voltage to the plurality of data lines DL.

The gate driving circuit GD may generate a scan signal and an emission signal based on the gate control signal. For example, the gate driving circuit GD may include a scan driver and an emission signal driver. The scan driver generates a scan signal in a row-sequential manner to drive at least one scan line connected to each pixel row and may supply the scan signal to the scan lines. The emission signal driver generates an emission signal in a-row sequential manner to drive at least one emission signal line connected to each pixel row to supply the emission signal to the emission signal lines.

Depending on the exemplary embodiment, the gate driving circuit GD may be disposed on the display panel PN in a gate-driver in panel (GIP) manner. For example, the gate driving circuit GD may be divided into a plurality of circuits and respectively disposed on at least two sides of the display panel PN.

The display panel PN may include a display area and a non-display area surrounding the display area.

The display area of the display panel PN may include multiple pixels PX disposed in the row direction and the column direction. For example, the plurality of pixels PX may be disposed in an area where the plurality of data lines DL and the plurality of gate lines GL intersect.

One pixel PX may include a plurality of sub pixels emitting light of different colors. For example, one pixel PX may implement blue, red, and green colors using three sub pixels. However, the present disclosure is not limited thereto, and in some cases, the pixel PX may further include a sub pixel for further implementing a specific color, for example, white.

In the pixel PX, an area implementing blue may be referred to as a blue sub pixel, an area implementing red may be referred to as a red sub pixel, and an area implementing green may be referred to as a green sub pixel.

Each of the plurality of pixels PX may include a first light emitting element and a second light emitting element which emit light of the same color.

Each of the plurality of pixels PX may include a first optical member that refracts light from the first light emitting element in a specific direction and a second optical member that refracts light from the second light emitting element in a specific direction. For example, each of the first optical member and the second optical member may be implemented as a lens, but the embodiment of the present disclosure is not limited thereto.

For example, the first optical member may be disposed in an optical area that provides light in a first range to form a first viewing angle, and the second optical member may be disposed in an optical area that provides light in a second range to form a second viewing angle. The second range may correspond to a range wider than the first range. Accordingly, the first optical member and the second optical member may limit the viewing angle of each of the plurality of pixels PX.

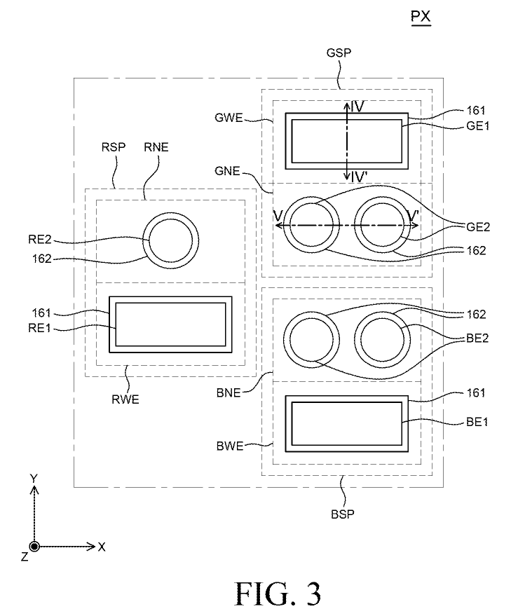

The first optical member and the second optical member will be described in detail below with reference to FIGS. 3 to 5.

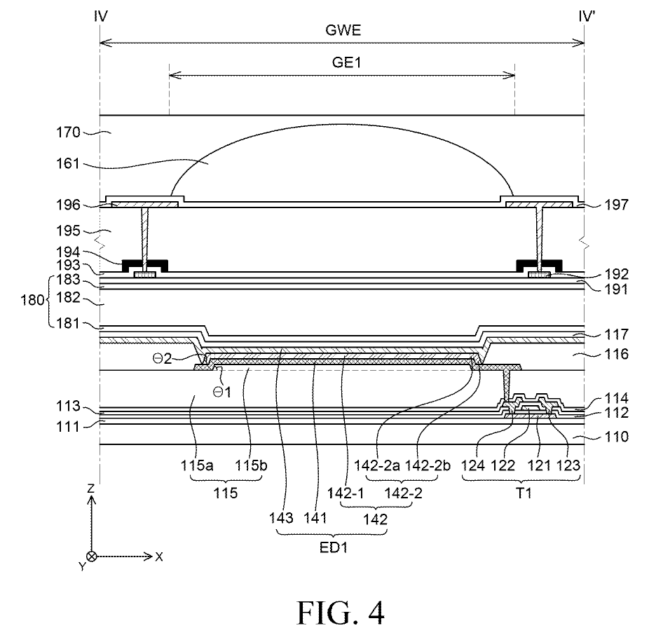

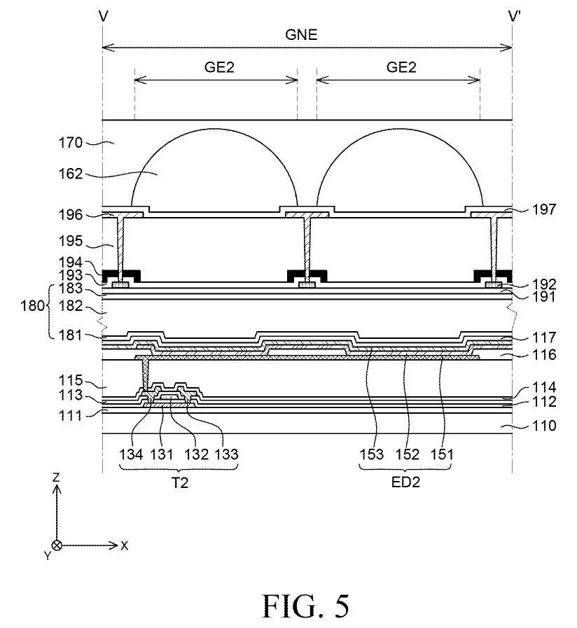

FIG. 3 is an enlarged plan view of a pixel of a display device according to an exemplary embodiment of the present disclosure. FIG. 4 is a cross-sectional view taken along IV-IV’ of FIG. 3. FIG. 5 is a cross-sectional view taken along V-V' in FIG. 3.

Meanwhile, FIG. 3 illustrates a plane of the pixel PX when the pixel PX includes three sub pixels, for example, a first sub pixel RSP, a second sub pixel GSP, and a third sub pixel BSP.

In addition, FIG. 4 illustrates a pixel in which the first optical member 161 is disposed as an embodiment of the display device 100 cut along IV-IV' in FIG. 3, and FIG. 5 illustrates a pixel in which the second optical member 162 is disposed as an embodiment of the display device 100 cut along V-V' in FIG. 3.

Meanwhile, for convenience of description, FIGS. 4 and 5 illustrate only areas corresponding to the first optical area GWE and the second optical area GNE of the second sub pixel GSP, among the three sub pixels RSP, GSP, and BSP illustrated in FIG. 3, but the other sub pixels RSP and BSP may also have the same configuration.

Meanwhile, for convenience of description, hereinafter, a horizontal direction on a plane is illustrated as a first direction X, and a vertical direction on a plane is illustrated as a second direction Y. Further, a normal direction of a plane defined by the first direction X and the second direction Y, for example, a thickness direction of the display device 100 may be defined as a third direction Z.

Referring to FIG. 3, the pixel PX may include a plurality of sub pixels RSP, GSP, and BSP representing different colors. For example, the pixel PX may include a first sub pixel RSP configured to implement red, a second sub pixel GSP configured to implement green, and a blue sub pixel BSP configured to implement blue. Depending on the exemplary embodiment, the first sub pixel RSP may be referred to as a red sub pixel, the second sub pixel GSP may be referred to as a green sub pixel, and the third sub pixel BSP may be referred to as a blue sub pixel. A pixel circuit may be disposed in each of the plurality of sub pixels RSP, GSP, and BSP included in the pixel PX.

Each of the plurality of sub pixels RSP, GSP, and BSP may include first optical areas RWE, GWE, and BWE and second optical areas RNE, GNE, and BNE that provide different viewing angles.

The first optical areas RWE, GWE, and BWE of the sub pixels RSP, GSP, and BSP may operate individually from the second optical areas RNE, GNE, and BNE of the corresponding pixel PX. For example, each sub pixel RSP, GSP, BSP may include a first light emitting element ED1 disposed in the first optical areas RWE, GWE, and BWE of the corresponding sub pixels RSP, GSP, and BSP, and a second light emitting element ED2 disposed in the second optical areas RNE, GNE, and BNE of the corresponding sub pixels RSP, GSP, and BSP.

In one pixel PX, the first light emitting element ED1 and the second light emitting element ED2 may be disposed in each of the first optical areas RWE, GWE, and BWE and the second optical areas RNE, GNE, and BNE of the plurality of sub pixels RSP, GSP, and BSP.

For example, in one pixel PX, a first light emitting element ED1 disposed in the first optical area RWE of the first sub pixel RSP, a second light emitting element ED2 disposed in the second optical area RNE of the first sub pixel RSP, a first light emitting element ED1 disposed in the first optical area GWE of the second sub pixel GSP, a second light emitting element ED2 disposed in the second optical area GNE of the second sub pixel GSP, a first light emitting element ED1 disposed in the first optical area BWE of the third sub pixel BSP, and a second light emitting element ED2 disposed in the second optical area BNE of the third sub pixel BSP may be disposed.

Referring to FIG. 3, in the first optical areas RWE, GWE, and BWE of the sub pixels RSP, GSP, and BSP, at least one first optical member 161 which is disposed so as to overlap with the first emission areas RE1, GE1, and BE1 of the first light emitting element ED1 may be disposed. At least one second optical member 162 which is disposed so as to overlap with the second emission areas RE2, GE2, and BE2 of the second light emitting element ED2 may be disposed in the second optical areas RNE, GNE, and BNE of the subpixels RSP, GSP, and BSP. In this case, the first optical areas RWE, GWE, and BWE may have a first viewing angle, and the second optical areas RNE, GNE, and BNE may have a second viewing angle smaller than the first viewing angle.

Referring to FIGS. 4 and 5 together, a display device 100 according to an exemplary embodiment of the present disclosure may include a substrate 110, a buffer layer 111, a gate insulating layer 112, an interlayer insulating layer 113, a passivation layer 114, a planarization layer 115, a bank 116, a capping layer 117, a first transistor T1, a second transistor T2, a first light emitting element ED1, a second light emitting element ED2, an encapsulation member 180, a touch buffer layer 191, a touch bridge electrode 192, a first touch insulating layer 193, a black matrix 194, a second touch insulating layer 195, a touch electrode 196, a third touch insulating layer 197, a first optical member 161, a second optical member 162, and an optical protective film 170.

The substrate 110 may include an insulating material. The substrate 110 may include a transparent material. For example, the substrate 110 may include glass or plastic.

A buffer layer 111 may be disposed on the substrate 110. The buffer layer 111 may include an insulating material. For example, the buffer layer 111 may include an inorganic insulating material such as silicon oxide (SiOₓ) and silicon nitride (SiNₓ). The buffer layer 111 may have a multilayer structure. For example, the buffer layer 111 may have a stacked structure of a layer made of silicon nitride (SiNₓ) and a layer made of silicon oxide (SiOₓ).

The buffer layer 111 may be positioned between the substrate 110 and a driving portion of each sub pixel RSP, GSP, BSP. The buffer layer 111 may prevent contamination due to the substrate 110 during a process of forming the driving portion. For example, an upper surface of the substrate 110 facing the driving portion of each sub pixel RSP, GSP, BSP may be covered by the buffer layer 111. The driving portion of each sub pixel RSP, GSP, BSP may be located on the buffer layer 111.

The gate insulating layer 112 may be disposed on the buffer layer 111. The gate insulating layer 112 may include an insulating material. For example, the gate insulating layer 112 may include an inorganic insulating material such as silicon oxide (SiOₓ) and silicon nitride (SiNₓ). The gate insulating layer 112 may include a material having a high dielectric constant. For example, the gate insulating layer 112 may include a high-K material such as hafnium oxide (HfO). The gate insulating layer 112 may have a multilayer structure.

The gate insulating layer 112 may extend between the semiconductor layers 121 and 131 and the gate electrodes 122 and 132 of the transistors T1 and T2. For example, the gate electrodes 122 and 132 of the first transistor T1 and the second transistor T2 may be insulated from the semiconductor layers 121 and 131 of the first transistor T1 and the second transistor T2 by the gate insulating layer 112. The gate insulating layer 112 may cover the semiconductor layers 121 and 131 of each sub pixel RSP, GSP, BSP. The gate electrodes 122 and 132 of the first transistor T1 and the second transistor T2 may be located on the gate insulating layer 112.

The interlayer insulating layer 113 may be disposed on the gate insulating layer 112. The interlayer insulating layer 113 may include an insulating material. For example, the interlayer insulating layer 113 may include an inorganic insulating material such as silicon oxide (SiOx) and silicon nitride (SiNx). The interlayer insulating layer 113 may extend between the gate electrodes 122 and 132 and the source electrodes 123 and 133 and between the gate electrodes 122 and 132 and the drain electrodes 124 and 134 of each of the transistors T1 and T2. For example, the source electrodes 123 and 133 and the drain electrodes 124 and 134 of the first transistor T1 and the second transistor T2 may be insulated from the gate electrodes 122 and 132 by the interlayer insulating layer 113. The interlayer insulating layer 113 may cover the gate electrodes 122 and 132 of the first transistor T1 and the second transistor T2. The source electrodes 123 and 133 and the drain electrodes 124 and 134 of each sub pixel RSP, GSP, BSP may be positioned on the interlayer insulating layer 113. The gate insulating layer 112 and the interlayer insulating layer 113 may expose a source region and a drain region of each of the semiconductor layers 121 and 131 positioned in each of the subpixels RSP, GSP, and BSP.

The passivation layer 114 may be disposed on the interlayer insulating layer 113. The passivation layer 114 may include an insulating material. For example, the passivation layer 114 may include an inorganic insulating material such as silicon oxide (SiOₓ) and silicon nitride (SiNₓ).

The passivation layer 114 may prevent damage to the driving portion due to external moisture and impact. The passivation layer 114 may extend along surfaces of the first transistor T1 and the second transistor T2. The passivation layer 114 may be in contact with the interlayer insulating layer 113 outside the driving portion located in each sub pixel RSP, GSP, BSP.

The planarization layer 115 may be disposed on the passivation layer 114. The planarization layer 115 may include an insulating material. The planarization layer 115 may include a material different from that of the passivation layer 114. For example, the planarization layer 115 may include an organic insulating material.

The planarization layer 115 may remove a step caused by a driving portion of each sub pixel RSP, GSP, BSP. For example, an upper surface of the planarization layer 115 facing the substrate 110 may be a flat surface.

Meanwhile, the planarization layer 115 may include a base portion 115a and a protrusion portion 115b disposed on the base portion 115a. The base portion 115a is disposed over the entire surface of the substrate 110 to remove a step caused by the driving portion of each sub pixel RSP, GSP, BSP.

The protrusion portion 115b may be disposed to overlap with the first emission areas RE1, GE1, and BE1 of the first light emitting element ED1. The protrusion portion 115b is disposed to overlap with the first light emitting element ED1 to change the shape of the first light emitting element ED1 so as to correspond to the protrusion portion 115b.

The protrusion portion115b may be disposed to be spaced apart from the bank 116 at a predetermined interval. Therefore, the first lower electrode 141 and the first light emitting layer 142 may be disposed between the bank 116 and the protrusion portion 115b.

For example, a cross-sectional shape of the protrusion portion 115b may be a trapezoidal shape. Therefore, the first light emitting layer 142 of the first light emitting element ED1 disposed on the protrusion portion 115b may have a step. For example, the first portion 142-1 corresponding to the center portion of the first light emitting layer 142 is disposed to overlap with the upper surface of the protrusion portion 115b and disposed flat, while the second portion 142-2 corresponding to the end of the first light emitting layer 142 is disposed to overlap with the side surface of the protrusion portion 115b, so that a part of the first portion 142-2 may be disposed to be inclined. That is, the protrusion portion 115b may increase the width of the first light emitting layer 142 in comparison with the case where the first light emitting layer 142 is disposed entirely flat. Accordingly, even if the second portion 142-2 is exposed to the out-gassing component and partially deteriorates and contracts, the second portion 142-2 that is not deteriorated or contracted remains, thereby minimizing the effect of the contraction.

Further, the protrusion portion 115b may allow the second portion 142-2 of the first light emitting layer 142 to be obliquely disposed so that the first portion 142-1 and the second portion 142-2 are disposed on different planes. For example, the protrusion portion 115b may minimize the propagation of the out-gassing component to the first portion 142-1 through the second portion 142-2 even though the second portion 142-2 is exposed to the out-gassing component by allowing at least a part of the first portion 142-1 of the first light emitting layer 142 of the first light emitting element ED1 to be disposed at a higher position than the second portion 142-2. Accordingly, shrinkage due to deterioration of the first portion 142-1 may be minimized.

Further, the protrusion portion 115b may allow the second portion 142-2 of the first light emitting layer 142 to include a flat portion 142-2a and an inclined portion 142-2b which have different emission angles. That is, the protrusion portion 115b varies the emission angle of the light emitted from the first light emitting layer 142 so that the luminance deviation according to the viewing angle may be improved. More details related to this will be described with reference to the first light emitting element ED1 to be described later.

The inclination angle θ1 of the protrusion portion 115b may be determined in consideration of an emission angle of light emitted from the first light emitting element ED1. For example, the inclination angle θ1 of the protrusion portion 115b may be 20° to 40°, but is not limited thereto.

In contrast, the protrusion portion 115b may not be disposed in the second emission areas RE2, GE2, and BE2 in which the second light emitting element ED2 is disposed. For example, the protrusion portion 115b is disposed in the first emission areas RE1, GE1, and BE1 to compensate for the luminance deviation according to the viewing angle, such that the first emission areas RE1, GE1, and BE1 are more effectively wide field of view mode.

However, the present disclosure is not limited thereto. The protrusion portion 115b may also be disposed in the second emission areas RE2, GE2, and BE2 in which the second light emitting element ED2 is disposed, if necessary.

The first transistor T1 and the second transistor T2 may be disposed on the substrate 110. The first transistor T1 may be electrically connected between the driving transistor and a first lower electrode 141 of the first light emitting element ED1. The second transistor T2 may be electrically connected between the driving transistor and a second lower electrode 151 of the second light emitting element ED2.

The first transistor T1 may include a first semiconductor layer 121, a first gate electrode 122, a first source electrode 123, and a first drain electrode 124. The first transistor T1 may have the same structure as the switching transistor and the driving transistor.

For example, the first semiconductor layer 121 may be positioned between the buffer layer 111 and the gate insulating layer 112, and the first gate electrode 122 may be positioned between the gate insulating layer 112 and the interlayer insulating layer 113. The first source electrode 123 and the first drain electrode 124 may be positioned between the interlayer insulating layer 113 and the passivation layer 114. The first gate electrode 122 may overlap with the channel region of the first semiconductor layer 121. The first source electrode 123 may be electrically connected to a source region of the first semiconductor layer 121. The first drain electrode 124 may be electrically connected to a drain region of the first semiconductor layer 121.

The second transistor T2 may include a second semiconductor layer 131, a second gate electrode 132, a second source electrode 133, and a second drain electrode 134. For example, the second semiconductor layer 131 may be positioned on the same layer as the first semiconductor layer 121, the second gate electrode 132 may be positioned on the same layer as the first gate electrode 122, and the second source electrode 133 and the second drain electrode 134 may be positioned on the same layer as the first source electrode 123 and the first drain electrode 124.

The first light emitting element ED1 and the second light emitting element ED2 of each sub pixel RSP, GSP, BSP may be disposed on the planarization layer 115 of the corresponding sub pixel RSP, GSP, BSP.

The first light emitting element ED1 may emit light representing a specific color. For example, the first light emitting element ED1 may include a first lower electrode 141, a first light emitting layer 142, and a first upper electrode 143 sequentially stacked on the substrate 110.

The first lower electrode 141 may be disposed on the protrusion portion 115b of the planarization layer 115 and the base portion 115a adjacent to the protrusion portion 115b. Accordingly, the first lower electrode 141 may be disposed along the shape of the protrusion portion 115b and include an inclined portion, but is not limited thereto.

The first lower electrode 141 may include a conductive material. The first lower electrode 141 may include a material having high reflectivity. For example, the first lower electrode 141 may include a metal such as aluminum (Al) and silver (Ag). The first lower electrode 141 may have a multilayer structure. For example, the first lower electrode 141 may have a structure in which a reflective electrode made of metal is positioned between transparent electrodes made of a transparent conductive material such as indium tin oxide (ITO) and indium zinc oxide (IZO). The first lower electrode 141 may be electrically connected to the first drain electrode 124 of the first transistor T1 through a contact hole passing through the passivation layer 114 and the planarization layer 115.

The first light emitting layer 142 may generate light of a luminance corresponding to a voltage difference between the first lower electrode 141 and the first upper electrode 143. For example, the first light emitting layer 142 may include an emission material layer (EML) including a light emitting material. The light emitting material may include an organic material, an inorganic material, or a hybrid material.

The first light emitting layer 142 may have a multilayer structure. For example, the first light emitting layer 142 may further include at least one of a hole injection layer (HIL), a hole transport layer (HTL), an electron transport layer (ETL), and an electron injection layer (EIL).

Meanwhile, the first light emitting layer 142 of the first light emitting element ED1 may include a first portion 142-1 and a second portion 142-2. Specifically, the first portion 142-1 may be a portion disposed at the center of the first light emitting layer 142. The second portion 142-2 may be a portion disposed at an end or edge of the first light emitting layer 142.

Specifically, the first portion 142-1 disposed in the central portion of the first light emitting layer 142 may be disposed to overlap with the upper surface of the protrusion portion 115b of the planarization layer 115. Accordingly, the first portion 142-1 may have a flat shape like the upper surface of the protrusion portion 115b, but is not limited thereto.

The second portion 142-2 disposed at the edge of the first light emitting layer 142 may be contracted by being more easily exposed to the out-gassing component of the planarization layer 115 than the first portion 142-1 and being deteriorated. Therefore, in order to minimize the influence of the contraction of the second portion 142-2, the second portion 142-2 may be disposed to overlap with the side surface of the protrusion portion 115b. Accordingly, the upper surface of the second portion 142-2 may include an inclined portion like the side surface of the protrusion portion 115b. Accordingly, the width of the second portion 142-2 may increase relatively compared to the case where the second portion 142-2 is disposed to be flat. That is, the second portion 142-2 is disposed to overlap with the side surface of the protrusion portion 115b to increase the width of the second portion 142-2 so that even if the second portion 142-2 is partially deteriorated, a portion that does not deteriorate may be secured. In other words, even if the second portion 142-2 is partially deteriorated and contracted, the second portion 142-2 that is not deteriorated or contracted remains, so that the effect of the contraction may be minimized. Therefore, the reduction of the first emission areas RE1, GE1, and BE1 may also be minimized.

Meanwhile, the second portion 142-2 overlapping with the side surface of the protrusion portion 115b of the planarization layer 115 may have a step difference. For example, the second portion 142-2 may include a flat portion 142-2a and an inclined portion 142-2b surrounding the flat portion 142-2a. The flat portion 142-2a may extend from the first portion 142-1 and may be disposed on the same plane as the first portion 142-1.

In contrast, the inclined portion 142-2b may extend from the flat portion 142-2a and may be disposed along the inclination of the protrusion portion 115b. Accordingly, at least a part of the inclined portion 142-2b may be disposed on a plane different from the flat portion 142-2a of the second portion 142-2 and the first portion 142-1. For example, at least a part of the inclined portion 142-2b may be disposed at a lower position than the flat portion 142-2a of the second portion 142-2 and the first portion 142-1. Accordingly, even if the inclined portion 142-2b disposed at the end of the first light emitting layer 142 is exposed to the out-gassing component, the propagation of the out-gassing component to the flat portion 142-2a of the second portion 142-2 and the first portion 142-1 is delayed because the flat portion 142-2a of the second portion 142-2 and the first portion 142-1 are disposed on a different plane from the inclined portion 142-2b. Accordingly, it is possible to minimize the propagation of the out-gassing component to the flat portion 142-2a of the second portion 142-2 and the first portion 142-1, and the contraction of the flat portion 142-2a of the second portion 142-2 and the first portion 142-1.

Accordingly, the width of the inclined portion 142-2b may be determined so that even if the inclined portion 142-2b is exposed to the out-gassing component, a portion that does not deteriorate may remain, and the out-gassing component may not propagate to the flat portion 142-2a of the second portion 142-2 and the first portion 142-1. For example, the width of the inclined portion 142-2b may be 0.8 μm to 1.2 μm. For example, the width of the inclined portion 142-2b may be about 1.0 μm. However, the present disclosure is not limited thereto. The inclined portion 142-2b may be designed in various ways depending on the size of the first light emitting element ED1.

Meanwhile, the inclination angle θ2 of the inclined portion 142-2b may be 20° to 40°. Accordingly, light emitted from the inclined portion 142-2b may be directed relatively laterally compared to the flat portion 142-2a. That is, the second portion 142-2 includes the flat portion 142-2a and the inclined portion 142-2b having different emission angles to control the optical path by adjusting the emission angle of light emitted from the first light emitting layer 142. In other words, even if the first light emitting element ED1 deteriorates, the optical path is adjusted to improve the luminance deviation according to the viewing angle.

The first upper electrode 143 may include a conductive material. The first upper electrode 143 may include a material different from that of the first lower electrode 141. The transmittance of the first upper electrode 143 may be higher than that of the first lower electrode 141. For example, the first upper electrode 143 may be a transparent electrode made of a transparent conductive material such as indium tin oxide (ITO) and indium zinc oxide (IZO). Accordingly, in the display device 100 according to the exemplary embodiment of the present disclosure, light generated by the first light emitting layer 142 may be emitted through the first upper electrode 143.

Like the first light emitting element ED1, the second light emitting element ED2 may include a second lower electrode 151, a second light emitting layer 152, and a second upper electrode 153 sequentially stacked on the substrate 110.

The second lower electrode 151 may correspond to the first lower electrode 141, the second light emitting layer 152 may correspond to the first light emitting layer 142, and the second upper electrode 153 may correspond to the first upper electrode 143. For example, the first light emitting element ED1 and the second light emitting element ED2 may be formed to have the same structure. However, it is not limited thereto and in some cases, at least some configurations of the first light emitting element ED1 and the second light emitting element ED2 may be formed differently.

In the embodiment, the second light emitting layer 152 may be spaced apart from the first light emitting layer 142. Accordingly, in the display device according to the exemplary embodiment of the present disclosure, light emission due to a leakage current may be prevented.

Meanwhile, unlike the first light emitting layer 142 of the first light emitting element ED1, the second light emitting layer 152 of the second light emitting element ED2 may not overlap with the protrusion portion 115b of the planarization layer 115. Therefore, the portion corresponding to the center area and the end area of the second light emitting layer 152 of the second light emitting element ED2 may be disposed on the same plane, but are not limited thereto.

According to the exemplary embodiment of the present disclosure, in the display device, light may be generated only in one of the first light emitting layer 142 and the second light emitting layer 152 according to a user's selection or a predetermined condition.

The second lower electrode 151 of each sub pixel RSP, GSP, BSP may be spaced apart from the first lower electrode 141 of the corresponding sub pixel RSP, GSP, BSP. For example, a bank 116 may be disposed between the first lower electrode 141 and the second lower electrode 151 of each sub pixel RSP, GSP, BSP. The bank 116 may include an insulating material. For example, the bank 116 may include an organic insulating material. The bank 116 may include a material different from that of the planarization layer 115.

The second lower electrode 151 of each sub pixel RSP, GSP, BSP may be insulated from the first lower electrode 141 of the corresponding sub pixel RSP, GSP, BSP by the bank 116. For example, the bank 116 may cover an edge of the first lower electrode 141 and an edge of the second lower electrode 151 located in each sub pixel RSP, GSP, BSP. The bank 116 may distinguish the first emission areas RE1, GE1, and BE1 of the first light emitting element ED1 and the second emission areas RE2, GE2, and BE2 of the second light emitting element ED2. For example, the first emission areas RE1, GE1, and BE1 of the first light emitting element ED1 may be divided by an edge area of the first lower electrode 141 covered by the bank 116. The second emission areas RE2, GE2, and BE2 of the second light emitting element ED2 may be divided by an edge area of the second lower electrode 151 covered by the bank 116.

In this case, referring to FIG. 3, the size of the first emission areas RE1, GE1, and BE1 of the first light emitting element ED1 divided in each sub pixel RSP, GSP, and BSP may be larger than the size of the second emission areas RE2, GE2, and BE2 of the second light emitting element ED2, but is not limited thereto.

The first light emitting layer 142 and the first upper electrode 143 of the first light emitting element ED1 located in each sub pixel RSP, GSP, BSP may be stacked on a partial area of the corresponding first lower electrode 141 exposed by the bank 116.

Specifically, the first light emitting layer 142 and the first upper electrode 143 may be stacked on the bank 116 and a partial area of the corresponding first lower electrode 141 exposed by the bank 116. The second light emitting layer 152 and the second upper electrode 153 of the second light emitting element ED2 positioned in each of the subpixels RSP, GSP, and BSP may be stacked on a partial area of the corresponding second lower electrode 151 exposed by the bank 116.

Specifically, the second light emitting layer 152 and the second upper electrode 153 may be stacked on the bank 116 and a partial area of the corresponding second lower electrode 151 exposed by the bank 116. The second upper electrode 153 of each sub pixel RSP, GSP, BSP may be electrically connected to the first upper electrode 143 of the corresponding sub pixel RSP, GSP, BSP. For example, a voltage applied to the second upper electrode 153 of the second light emitting element ED2 located in each sub pixel RSP, GSP, BSP may be equal to a voltage applied to the first upper electrode 143 of the first light emitting element ED1 located in the corresponding sub pixel RSP, GSP, BSP. The second upper electrode 153 of each sub pixel RSP, GSP, BSP may include the same material as the first upper electrode 143 of the corresponding sub pixel RSP, GSP, BSP. For example, the second upper electrode 153 of each sub pixel RSP, GSP, BSP may be formed simultaneously with the first upper electrode 143 of the corresponding sub pixel RSP, GSP, BSP. The second upper electrode 153 of each sub pixel RSP, GSP, BSP may extend onto the bank 116 to be in direct contact with the first upper electrode 143 of the corresponding sub pixel RSP, GSP, BSP. Luminance of the first optical areas RWE, GWE, and BWE and luminance of the second optical areas RNE, GNE, and BNE located in each sub pixel RSP, GSP, BSP may be controlled by a driving current generated in the corresponding sub pixel RSP, GSP, BSP.

A capping layer 117 may be disposed on the first light emitting element ED1 and the second light emitting element ED2 of each sub pixel RSP, GSP, BSP. The capping layer 117 may prevent damage to the light emitting elements ED1 and ED2 due to external moisture and impact. For example, the capping layer 117 may be formed of an inorganic insulating material such as silicon oxide (SiOₓ) or silicon nitride (SiNₓ), but is not limited thereto and may be formed of an organic insulating material.

The encapsulation member 180 may be located on the capping layer 117. The encapsulation member 180 may prevent damage to the light emitting elements ED1 and ED2 due to external moisture and impact. The encapsulation member 180 may have a multilayer structure. For example, the encapsulation member 180 may include a first encapsulation layer 181, a second encapsulation layer 182, and a third encapsulation layer 183 sequentially stacked, but is not limited thereto.

The first encapsulation layer 181, the second encapsulation layer 182, and the third encapsulation layer 183 may include an insulating material. The second encapsulation layer 182 may include a material different from those of the first encapsulation layer 181 and the third encapsulation layer 183. For example, the first encapsulation layer 181 and the third encapsulation layer 183 are inorganic encapsulation layers including an inorganic insulating material, and the second encapsulation layer 182 may include an organic encapsulation layer including an organic insulating material. Accordingly, the light emitting elements ED1 and ED2 of the display device 100 may be more effectively prevented from being damaged by external moisture and impact.

The touch buffer layer 191 may be disposed on the encapsulation member 180. The touch buffer layer 191 may be disposed between the encapsulation member 180 and the touch bridge electrode 192 to insulate the touch bridge electrode 192. For example, the touch buffer layer 191 may include an insulating material. For example, the touch buffer layer 191 may be formed of an organic insulating material or an inorganic insulating material, but is not limited thereto.

The touch bridge electrode 192 may be disposed on the touch buffer layer 191. The touch bridge electrode 192 may be disposed in the first optical areas RWE, GWE, and BWE and the second optical areas RNE, GNE, and BNE located in the sub pixels RSP, GSP, and BSP. For example, the touch bridge electrode 192 may be disposed in the first emission areas RE1, GE1, and BE1 of the first optical areas RWE, GWE, and BWE and the second emission areas RE2, GE2, and BE2 of the second optical areas RNE, GNE, and BNE.

For example, the touch bridge electrode 192 may include a metal material such as titanium (Ti), aluminum (Al), silver (Ag), copper (Cu), and a magnesium-silver alloy (Mg:Ag), but is not limited thereto.

The first touch insulating layer 193 may be disposed on the touch bridge electrode 192. The first touch insulating layer 193 may be disposed between the touch bridge electrode 192 and the black matrix 194 to insulate the touch bridge electrode 192.

The first touch insulating layer 193 may include an insulating material. For example, the first touch insulating layer 193 may include an organic insulating material or an inorganic insulating material, but is not limited thereto.

A black matrix 194 may be disposed on the first touch insulating layer 193. The black matrix 194 may be disposed between the plurality of sub pixels RSP, GSP, and BSP to reduce a color mixture of the plurality of sub pixels RSP, GSP, and BSP. Accordingly, the black matrix 194 may be disposed to overlap with the bank 116.

A second touch insulating layer 195 may be disposed on the black matrix 194. The second touch insulating layer 195 may be disposed between the black matrix 194 and the touch electrode 196 to insulate the touch electrode 196.

The second touch insulating layer 195 may include an insulating material. For example, the second touch insulating layer 195 may include an organic insulating material or an inorganic insulating material, but is not limited thereto.

A plurality of touch electrodes 196 may be disposed on the second touch insulating layer 195. The plurality of touch electrodes 196 may be configured to sense an external touch input using a user's finger or a touch pen. The touch electrode TE may include, for example, a metal material such as titanium (Ti), aluminum (Al), silver (Ag), copper (Cu), and a magnesium-silver alloy (Mg:Ag), but is not limited thereto.

A third touch insulating layer 197 may be disposed on the touch electrode 196. The third touch insulating layer 197 may be disposed between the touch electrode 196 and the optical member 160 to insulate the touch electrode 196.

The third touch insulating layer 197 may include an insulating material. For example, the third touch insulating layer 197 may include an organic insulating material or an inorganic insulating material, but is not limited thereto.

Referring to FIGS. 4 and 5, the first optical member 161 and the second optical member 162 may be disposed on the third touch insulating layer 197.

For example, each of the first optical member 161 and the second optical member 162 may be disposed to cover edges of the plurality of touch electrodes 196, but is not limited thereto and may be disposed not to overlap with the plurality of touch electrodes 196.

The first optical member 161 may be disposed on the first light emitting element ED1. Light generated by the first light emitting element ED1 of each sub pixel RSP, GSP, BSP may be emitted through the first optical member 161 disposed in the first optical areas RWE, GWE, and BWE of the corresponding sub pixel RSP, GSP, BSP.

The first optical member 161 may have a shape in which light in at least one direction may not be restricted. For example, a planar shape of the first optical member 161 located in each sub pixel RSP, GSP, BSP may have a bar shape extending in the first direction X.

In this case, the traveling direction of the light emitted from the first optical areas RWE, GWE, and BWE of the sub pixels RSP, GSP, and BSP may not be limited to the first direction X. For example, the content (or images) provided through the first optical areas RWE, GWE, and BWE of the sub pixels RSP, GSP, and BSP may be shared with surrounding people adjacent to the user in the first direction X. Accordingly, the content provided by the light emitted through the first optical member 161 may be provided within first viewing angle range, which is wider than the viewing angle range of the content provided by light emitted through the second optical member 162. For example, the content provided by the light emitted through the first optical member 161 may be provided in a wide field of view mode (share mode).

The second optical member 162 may be disposed on the second light emitting element ED2. Light generated by the second light emitting element ED2 of each sub pixel RSP, GSP, BSP may be emitted through the second optical member 162 disposed in the second optical areas RNE, GNE, and BNE of the corresponding sub pixel RSP, GSP, BSP. The second optical member 162 may limit the traveling direction of light passing through the second optical member 162 to the first direction X and/or the second direction Y. For example, a planar shape of the second optical member 162 located in each sub pixel RSP, GSP, BSP may have a circular shape. However, the present disclosure is not limited thereto, and the planar shape of the second optical member 162 positioned in each of the sub pixels RSP, GSP, and BSP may have a polygonal shape.

In this case, a traveling direction of light emitted from the second optical areas RNE, GNE, and BNE of the sub pixels RSP, GSP, and BSP may be limited to the first direction X and/or the second direction Y. For example, the content (or images) provided by the second optical areas RNE, GNE, and BNE of the sub pixels RSP, GSP, and BSP may not be shared with people around the user. Accordingly, the content provided by the light emitted through the second optical member 162 may be provided within the second viewing angle range, which is narrower than the viewing angle range of the content provided through the first optical member 161. For example, the content provided by the light emitted through the second optical member 162 may be provided in a narrow field of view mode (private mode).

The first emission areas RE1, GE1, and BE1 of each pixel PX may have a shape corresponding to the first optical member 161 of the corresponding sub pixels RSP, GSP, and BSP. For example, the planar shape of the first emission areas RE1, GE1, and BE1 of each sub pixel RSP, GSP, BSP may have a bar shape extending in the first direction X. The first optical member 161 may have a larger size than the first emission areas RE1, GE1, and BE1 of the corresponding sub pixels RSP, GSP, and BSP. Accordingly, the efficiency of light emitted from the first emission areas RE1, GE1, and BE1 of the sub pixels RSP, GSP, and BSP may be improved.

In addition, the first optical member 161 may have a greater width than the area of the protrusion portion 115b of the planarization layer 115. Accordingly, all light having various emission angles may be emitted through the first optical member 161 due to the protrusion portion 115b, thereby improving light emission efficiency.

The second emission areas RE2, GE2, and BE2 of the sub pixels RSP, GSP, and BSP may have a shape corresponding to the second optical member 162 of the corresponding sub pixels RSP, GSP, and BSP. For example, a planar shape of the second emission areas RE2, GE2, and BE2 of the sub pixels RSP, GSP, and BSP may have a circular or polygonal shape. The second optical member 162 may have a larger size than the second emission areas RE2, GE2, and BE2 of the corresponding sub pixels RSP, GSP, and BSP. Accordingly, the efficiency of light emitted from the second emission areas RE2, GE2, and BE2 of the sub pixels RSP, GSP, and BSP may be improved.

Depending on the exemplary embodiment, the first optical area RWE, GWE, BWE of one sub pixel RSP, GSP, BSP may include one first emission area RE1, GE1, BE1. Further, the second optical area RNE, GNE, BNE of one sub pixel RSP, GSP, BSP may include a plurality of second emission areas RE2, GE2, BE2.

Depending on the exemplary embodiment, one first optical member 161 may be disposed on the first optical areas RWE, GWE, BWE of one sub pixel RSP, GSP, BSP. Further, a plurality of second optical members 162 may be disposed on the second optical area RNE, GNE, BNE of one sub pixel RSP, GSP, BSP.

Referring to FIG. 3, the number of second emission areas RE2, GE2, and BE2 may vary for each sub pixel RSP, GSP, BSP. For example, the number of second emission areas GE2 defined in the second optical area GNE of the second sub pixel GSP and the number of second emission areas BE2 defined in the second optical area BNE of the third sub pixel BSP may be larger than the number of second emission areas RE2 defined in the second optical area RNE of the first sub pixel RSP. In this case, the efficiency deviation of the second light emitting elements ED2 positioned on the second optical areas RNE, GNE, and BNE may be compensated by the number of second emission areas RE2, GE2, and BE2 defined in the second optical areas RNE, GNE, and BNE of the sub pixels RSP, GSP, and BSP.

The optical member protection film 170 may be positioned on the first optical member 161 and the second optical member 162 of the sub pixels RSP, GSP, and BSP. The optical member protection film 170 may include an insulating material. For example, the optical member protective film 170 may include an organic insulating material. The refractive index of the optical member protection film 170 may be smaller than the refractive index of the first optical member 161 and the refractive index of the second optical member 162 located in each sub pixel RSP, GSP, BSP. Accordingly, in the display device 100 according to the exemplary embodiment of the present disclosure, light passing through the first optical member 161 and the second optical member 162 of each sub pixel RSP, GSP, BSP may not be reflected toward the substrate 110 due to a difference in refractive index from the optical member protection film 170.

The portion of the light emitting layer disposed at the end of the light emitting element is more easily exposed to the outgassing component than the portion disposed at the center, and thus may be relatively easily deteriorated. When the light emitting layer deteriorates as described above, the light emitting layer may shrink and thus the emission area may be reduced.

Meanwhile, in the display device, the light emitting element may be selectively driven according to a user's selection or a predetermined condition. Accordingly, some of the light emitting elements may be continuously driven, while others may have a relatively short driving time. At this time, some of the continuously driven light emitting elements generate a lot of heat, and thus may be relatively easily deteriorated. As described above, when the degree of deterioration is different for each light emitting element, a deviation may occur even in the degree of contraction of the light emitting element. In other words, a deviation may occur even in the size of the emission area between the light emitting elements, which may lead to a luminance deviation for each area.

Accordingly, in the display device 100 according to the exemplary embodiment of the present disclosure, the planarization layer 115 may include the protrusion portion 115b disposed to overlap with the first light emitting element ED1. Therefore, the first light emitting layer 142 of the first light emitting element ED1 may be disposed along the shape of the protrusion portion 115b. For example, when the protrusion portion 115b has a trapezoidal shape, the first light emitting layer 142 may have a step. Specifically, the first portion 142-1 disposed in the central portion of the first light emitting layer 142 is disposed to overlap with the upper surface of the protrusion portion 115b and may be formed in a flat shape. In contrast, the second portion 142-2 disposed at the end of the first light emitting layer 142 is disposed to overlap with the side surface of the protrusion portion 115b so that a part of the second portion 142-2 may be inclined. That is, in the display device 100 according to the exemplary embodiment of the present disclosure, the second portion 142-2 is obliquely disposed to increase the width of the first light emitting layer 142 relatively compared to the case where the first light emitting layer 142 is disposed to be flat as a whole. Accordingly, even if the second portion 142-2 is exposed to the out-gassing component and partially deteriorates, the remaining portion that does not deteriorate may remain. Accordingly, the effect of the shrinkage due to the deterioration of the first light emitting layer 142 may be minimized, and therefore, the shrinkage of the first emission areas RE1, GE1, and BE1 may be minimized. Accordingly, even if there is a difference in the degree of deterioration of the first light emitting element ED1, the size deviation between the first emission areas RE1, GE1, and BE1 may be minimized. Accordingly, it is possible to minimize the luminance deviation between the first light emitting elements ED1 according to the viewing angle.

Further, in the display device 100 according to the exemplary embodiment of the present disclosure, the second portion 142-2 has an inclination so that the first portion 142-1 and the second portion 142-2 may be disposed on different planes. Specifically, the second portion 142-2 may include a flat portion 142-2a and an inclined portion 142-2b surrounding the flat portion 142-2a. For example, the flat portion 142-2a extends from the first portion 142-1 to be disposed on the same plane as the first portion 142-1, while the inclined portion 142-2b extends from the flat portion 142-2a to be disposed along the inclination of the protrusion portion 115b. Therefore, at least a part of the inclined portion 142-2b may be disposed at a lower position than the flat portion 142-2a of the second portion 142-2 and the first portion 142-1. Accordingly, even if the inclined portion 142-2b disposed at the most end of the first light emitting layer 142 is exposed to the out-gassing component, propagation of the out-gassing component to the flat portion 142-2a of the second portion 142-2 and the first portion 142-1 disposed on a plane different from the inclined portion 142-2b may be delayed. Therefore, deterioration and subsequent contraction of the flat portion 142-2a of the second portion 142-2 and the first portion 142-1 due to the out-gassing may be minimized.

Further, in the display device 100 according to the exemplary embodiment of the present disclosure, the first light emitting layer 142 of the first light emitting element ED1 may include not only the flat portions 142-2a of the second portion 142-2 and the first portions 142-1 disposed flat, but also the inclined portions 142-2b. In this case, light emitted by the flat portion 142-2a and the inclined portion 142-2b may be emitted at different emission angles. That is, in the display device 100 according to the exemplary embodiment of the present disclosure, the protrusion portion 115b disposed to overlap with the first light emitting element ED1 is formed on the planarization layer 115 to variously adjust the emission angle of light emitted from the first light emitting layer 142 to control the light path. Therefore, even though deterioration of the first light emitting element ED1 occurs, the optical path is adjusted to improve the luminance deviation according to the viewing angle. Accordingly, by implementing uniform luminance, the display quality of the display device 100 may be improved.

The exemplary embodiment of the present disclosure can also be described:

According to an aspect of the present disclosure, a display device includes a substrate, a planarization layer disposed on the substrate and including a base portion and a protrusion portion disposed on the base portion, a light emitting element disposed on the planarization layer and including a first electrode disposed on a part of the base portion adjacent to the protrusion portion, a light emitting layer disposed on the first electrode and a second electrode disposed on the light emitting layer, and an optical member having a bar shape disposed on the light emitting element. The light emitting layer includes a first portion disposed in a center portion and a second portion surrounding the first portion and disposed at an end. The first portion is disposed to overlap with an upper surface of the protrusion portion. The second portion is disposed to overlap with a side surface of the protrusion portion.

The first portion may be disposed at a position higher than at least a portion of the second portion.

The first portion may have a flat shape and the second portion may have a step.

The second portion may include a flat portion and an inclined portion disposed to surround the flat portion, and an inclination angle of the inclined portion may be 20° to 40°.

The width of the inclined portion may be 0.8 μm to 1.2 μm.

The cross-sectional shape of the protrusion portion may be trapezoidal.

The display device may further include a bank disposed on the planarization layer and defining an emission area and a non-emission area. The protrusion portion may be disposed to overlap with the emission area.

According to another aspect of the present disclosure, a display device includes a substrate including a display area in which a plurality of sub pixels is defined and a non-display area surrounding the display area, a planarization layer disposed on the substrate, a first light emitting element and a second light emitting element disposed in each of the plurality of sub pixels, a first optical member disposed on the first light emitting element and having a semi-cylindrical shape, and a second optical member disposed on the second light emitting element and having a semi-spherical shape, wherein the first light emitting element and the second light emitting element each include a first electrode, a light emitting layer, and a second electrode. The light emitting layer includes a first portion disposed in a center portion, and a second portion disposed at an edge of the first portion. The planarization layer includes a protrusion portion disposed to overlap with the first light emitting element.

The first portion of the first light emitting element may be disposed on a plane different from at least a portion of the second portion of the first light emitting element.

The protrusion portion may be disposed to overlap with only the first light emitting element among the first light emitting element and the second light emitting element.

The display device may further include a bank disposed on the planarization layer and defining an emission area and a non-emission area, and the protrusion portion may be disposed to overlap with only the emission area of the first light emitting element among the emission area of the first light emitting element and the emission area of the second light emitting element.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A display device, comprising:
a substrate;
a planarization layer disposed on the substrate, wherein the planarization layer comprises a base portion and a protrusion portion disposed on the base portion;
a light emitting element disposed on the planarization layer, wherein the light emitting element comprises a first electrode disposed on the protrusion portion, a portion of the base portion adjacent to the protrusion portion, a light emitting layer disposed on the first electrode, and a second electrode disposed on the light emitting layer; and
an optical member having a bar shape disposed on the light emitting element,
wherein the light emitting layer comprises a first portion disposed at a center portion and a second portion surrounding the first portion and disposed at an end,
wherein the first portion is disposed to overlap with an upper surface of the protrusion portion, and
wherein the second portion is disposed to overlap with a side surface of the protrusion portion.

2. The display device according to claim 1, wherein the first portion is disposed at a position higher than at least a part of the second portion.

3. The display device according to claim 1, wherein the first portion has a flat shape, and wherein the second portion has a step.

4. The display device according to claim 1, wherein the second portion comprises a flat portion and an inclined portion disposed to surround the flat portion, and
wherein an inclination angle of the inclined portion is 20° to 40°.

5. The display device according to claim 4, wherein a width of the inclined portion is 0.8 μm to 1.2 μm.

6. The display device according to claim 1, wherein the protrusion portion has a trapezoidal cross-sectional shape.

7. The display device according to claim 1, further comprising:
a bank disposed on the planarization layer,
wherein the bank defines an emission area and a non-emission area, and
wherein the protrusion portion is disposed so as to overlap with the emission area.

8. A display device, comprising:
a substrate comprising an active area in which a plurality of sub pixels is defined and a non-active area which encloses the active area;
a planarization layer disposed on the substrate;
a first light emitting element;
a second light emitting element disposed in each of the plurality of sub pixels;
a first optical member disposed on the first light emitting element, wherein the first optical member is semi-cylindrical; and
a second optical member disposed on the second light emitting element, wherein the second optical member is semi-spherical,
wherein the first light emitting element and the second light emitting element each comprise a first electrode, a light emitting layer, and a second electrode,
wherein the light emitting layer comprises a first portion disposed in a center portion and a second portion disposed at an edge, wherein the second portion encloses the first portion, and
wherein the planarization layer comprises a protrusion portion disposed to overlap with the first light emitting element.

9. The display device according to claim 8, wherein the first portion of the first light emitting element is disposed on a plane different from at least a part of the second portion of the first light emitting element.

10. The display device according to claim 8, wherein the protrusion portion is disposed so as to overlap with only the first light emitting element among the first light emitting element and the second light emitting element.

11. The display device according to claim 8, further comprising:
a bank disposed on the planarization layer, wherein the bank defines an emission area and a non-emission area,
wherein the protrusion portion is disposed so as to overlap only with the emission area of the first light emitting element among the emission area of the first light emitting element and the emission area of the second light emitting element.
